(19) United States
(12) Patent Application Publication
(10) Pub. No.: US 2025/0212652 A1
(43) Pub. Date: Jun. 26, 2025

(54) DISPLAY DEVICE

(71) Applicant: Samsung Display Co., LTD., Yongin-si (KR)

(72) Inventors: Jong Suk LEE, Yongin-si (KR); Kwan Bae KONG, Yongin-si (KR); Ji Hoon SONG, Yongin-si (KR); Yong Hwan YOON, Yongin-si (KR)

(21) Appl. No.: 18/822,227

(22) Filed: Sep. 1, 2024

(30) Foreign Application Priority Data
Dec. 21, 2023 (KR) 10-2023-0188754

(51) Int. Cl. H10K 59/80

(52) U.S. Cl. CPC H10K 59/8722; H10K 59/872; H10K 59/8792; H10K 59/8793

(57) ABSTRACT

A display device includes: a display stack structure, an optical adhesive member disposed on the display stack structure, and a cover window disposed on a the optical adhesive member. The cover window includes a front surface, a first side surface extended from the front surface in a first direction and bent, a second side surface extended from the front surface in a second direction and bent, and a corner located between the first side surface and the second side surface. The cover window includes an inner surface adjacent to the display stack structure and an outer surface opposed to the inner surface, and the outer surface of the cover window has a first radius of curvature, and the inner surface of the cover window has a second radius of curvature greater than the first radius of curvature at the corner.

This application claims priority to Korean Patent Application No. 10-2023-0188754, filed on Dec. 21, 2023, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

As display devices are employed by various electronic devices, display devices are required to have various designs. For example, images can be displayed not only on the front surface of a display device but also on the curved portions at four edges of the front surface and on the corners between the curved portions.

### SUMMARY

Aspects of the present disclosure provide a display device that can prevent adhesion failure at corners.

It should be noted that objects of the present disclosure are not limited to the above-mentioned object; and other objects of the present disclosure will be apparent to those skilled in the art from the following descriptions.

According to an aspect of the present disclosure, a display device includes: a display stack structure including at least a display panel; an optical adhesive member disposed on a surface of the display stack structure; and a cover window disposed on a surface of the optical adhesive member opposed to the display stack structure, where the cover window includes a front surface, a first side surface extended from the front surface in a first direction and having a curvature, a second side surface extended from the front surface in a second direction intersecting the first direction and having a curvature, and a corner located between the first side surface and the second side surface and having the curvature of the first side surface and the curvature of the second side surface, the cover window includes an inner surface adjacent to the display stack structure and an outer surface opposed to the inner surface, and the outer surface of the cover window has a first radius of curvature, and the inner surface of the cover window has a second radius of curvature greater than the first radius of curvature at the corner.

In an embodiment, an entirety of the outer surface of the cover window may have the first radius of curvature at the corner.

In an embodiment, the second radius of curvature of the inner surface may gradually decrease toward the first side surface or the second side surface at the corner.

In an embodiment, the second radius of curvature may be the largest at a position at 45 degrees with respect to the first direction at the corner.

In an embodiment, the second radius of curvature may gradually decrease toward the first side surface or the second side surface from the position at 45 degrees with respect to the first direction at the corner.

In an embodiment, a thickness of the cover window may gradually decrease from the front surface to a side of the cover window opposed to the front surface at the corner.

In an embodiment, a thickness of the cover window may gradually increase toward the first side surface or the second side surface from the position at 45 degrees with respect to the first direction at the corner.

In an embodiment, the thickness of the cover window may be smallest at the position at 45 degrees with respect to the first direction at the corner.

In an embodiment, the display device may further include: a black matrix disposed between the cover window and the optical adhesive member, where the black matrix may overlap with the first side surface, the second side surface and the corner but not overlap with the front surface in a plan view.

In an embodiment, the inner surface of the cover window may include a first inner surface that does not overlap with the black matrix and a second inner surface that overlaps with the black matrix at the corner in the plan view, and a radius of curvature of the first inner surface may be equal to the first radius of curvature, and a radius of curvature of the second inner surface may be greater than the first radius of curvature.

In an embodiment, the display device may further include: a protective member disposed in a space defined by the cover window and the display stack structure, and the protective member may overlap with the corner of the cover window in the plan view.

In an embodiment, the protective member may include one of a silicone resin, polyimide, and polyethylene terephthalate.

In an embodiment, the display device may further include: a dam disposed on a rear surface of the display stack structure, and the dam may overlap with the corner of the cover window in the plan view.

In an embodiment, the display stack structure may further include: a cover panel disposed on a first surface of the display panel, and a polarizing member disposed on a second surface of the display panel opposed to the first surface, and a side surface of the optical adhesive member may protrude outward from a side surface of the polarizing member and the display panel, and the side surface of the polarizing member and the display panel may protrude outward from a side surface of the cover panel in the plan view.

According to an aspect of the present disclosure, a display device includes: a display stack structure including at least a display panel; an optical adhesive member disposed on a surface of the display stack structure; a cover window disposed on a surface of the optical adhesive member opposed to the display stack structure; and a protection member disposed in a space defined by the cover window and the display stack structure, where the cover window includes: a front surface, a first side surface extended from the front surface in a first direction and having a curvature, a second side surface extended from the front surface in a second direction intersecting the first direction and having a curvature, and a corner located between the first side surface and the second side surface and having the curvature of the first side surface and the curvature of the second side surface, the cover window includes an inner surface adjacent to the display stack structure and an outer surface opposed to the inner surface, and the protective member overlaps with the corner of the cover window but does not overlap with the front surface, the first side surface and the second side surface in a plan view.

In an embodiment, the display device may further include a black matrix disposed between the cover window and the optical adhesive member and overlapping with the corner in the plan view, and the protective member is in contact with the black matrix and side surfaces of the display stack structure.

In an embodiment, the protective member may include one of a silicone resin, polyimide, and polyethylene terephthalate.

In an embodiment, the display device may further include a dam disposed on a surface of the display stack structure, where the dam overlaps with the corner of the cover window in the plan view.

In an embodiment, the protective member may be in contact with a side surface of the dam but may not overlap with an upper surface of the dam.

In an embodiment, the display stack structure may further include a cover panel disposed on a first surface of the display panel, and a polarizing member disposed on a second surface of the display panel opposed to the first surface, and a side surface of the optical adhesive member may protrude outward from a side surface of the polarizing member and the display panel, and the side surface of the polarizing member and the display panel may protrude outward from a side surface of the cover panel in the plan view.

According to an embodiment of the present disclosure, the radius of curvature of the inner surface of corners of a cover window of a display device is formed to be larger than the radius of curvature of the outer surface, thereby reducing compressive stress applied to a display stack structure to suppress buckling failure.

In addition, according to an embodiment of the present disclosure, a protective member is formed between the cover window and the display stack structure at the corners of the cover window of the display device, so that it is possible to prevent deformation of the display stack structure due to stress and to prevent permeation of moisture, thereby improving the reliability.

In addition, according to an embodiment of the present disclosure, a dam is disposed on a surface of the display stack structure in a display device, so that the amount of protective member can be increased to further improve the reliability of the display stack structure.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment of the present disclosure.

FIG. 2 is a plan view showing a display device according to an embodiment of the present disclosure.

FIG. 3 is a cross-sectional view showing an example of a display panel taken along line Q1-Q1′ of FIG. 2.

FIG. 4 is a plan view schematically showing pixels of a display area of a display device according to an embodiment.

FIG. 5 is a cross-sectional view taken along line Q2-Q2′ of FIG. 4.

FIG. 6 is a plan view showing a display device except for a cover window according to an embodiment.

FIG. 7 is a cross-sectional view showing an example of the display device taken along line Q3-Q3′ of FIG. 6.

FIG. 8 is a cross-sectional view showing an example of the display device taken along line Q4-Q4′ of FIG. 6.

FIG. 9 is a perspective view schematically showing a third corner portion of the display device according to the embodiment.

FIG. 10 is a cross-sectional view showing another example of the display device taken along line Q3-Q3′ of FIG. 6.

FIG. 11 is a plan view showing an example of a display device to another embodiment of the present disclosure.

FIG. 12 is a cross-sectional view taken along line Q5-Q5′ of FIG. 11.

FIG. 13 is a plan view showing an example of a display device to still another embodiment of the present disclosure.

FIG. 14 is a cross-sectional view taken along line Q6-Q6′ of FIG. 11.

FIG. 15 is a plan view showing an example of a display device to yet another embodiment of the present disclosure.

FIG. 16 is a cross-sectional view taken along line Q7-Q7′ of FIG. 16.

FIG. 17 is a rear perspective view schematically showing a third corner of a cover window.

FIG. 18 is a table showing results of the reliability test of display devices.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments of the present disclosure will be described with reference to the accompanying drawings.

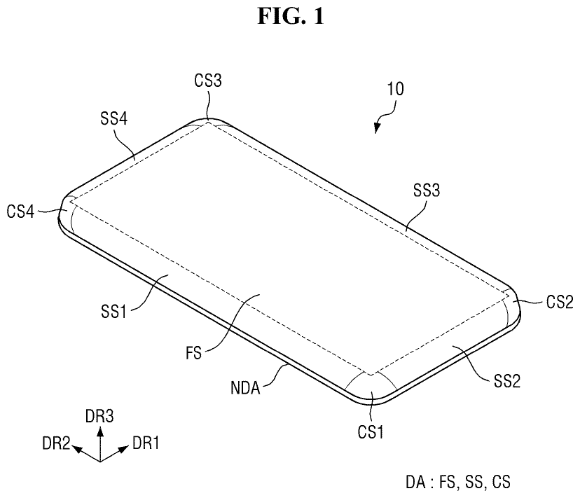

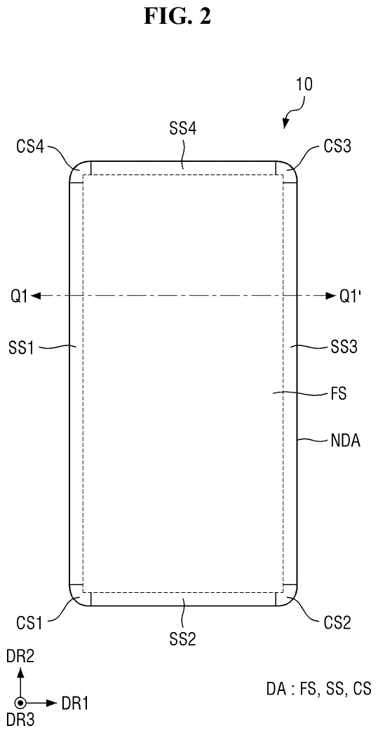

FIG. 1 is a perspective view showing a display device according to an embodiment of the present disclosure. FIG. 2 is a plan view showing a display device according to an embodiment of the present disclosure. As used herein, the “plan view” is a view from above (i.e., third direction DR3).

Referring to FIGS. 1 and 2, the display device 10 according to the embodiment may include a variety of devices that display images or videos. For example, the display device 10 according embodiments of the present disclosure may be applied to a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc., in addition to a smart phone.

As used herein, the shorter sides of the display device 10 may be extended in parallel to the first direction DR1, and the longer sides of the display device 10 may be extended in parallel to the second direction DR2 when viewed from the top. For example, the first direction DR1 and the second direction DR2 may intersect each other such that they are perpendicular to each other, the first direction DR1 may be the horizontal direction of the display device 10 when viewed from the top, and the second direction DR2 may be the vertical direction of the display device 10 when viewed from the top. The third direction DR3 may be perpendicular to the first direction DR1 as well as the second direction DR2 and may refer to the thickness direction of the display device 1, for example.

The display device 10 may include a display area DA and a non-display area NDA.

In the display area DA, images may be displayed. The display area DA may include pixels and/or emission areas. The display area DA may include a front surface FS, side surfaces SS: SS1, SS2, SS3 and SS4, and corners CS: CS1, CS2, CS3 and CS4. The front surface FS, the side surfaces SS: SS1, SS2, SS3 and SS4, and the corners CS: CS1, CS2, CS3 and CS4 may be substantially included in a cover window CW to be described below.

The entire front surface FS may be substantially flat, but the present disclosure is not limited thereto. At least a portion of the front surface FS may include a convex or concave shape in the thickness direction (the third direction DR3) in another embodiment. The front surface FS may include a rectangular shape having shorter sides in the first direction DR1 and longer sides in the second direction DR2. The front surface FS may have rounded corners when viewed from the top. The front surface FS may have rounded polygonal corners when viewed from the top. In an embodiment, for example, as shown in FIG. 1, the front surface FS may have a rectangular shape with rounded corners, but the present disclosure is not limited thereto.

The side surfaces SS: SS1, SS2, SS3 and SS4 may be extended outward from the edges of the front surface FS to be bent at a predetermined angle. In an embodiment, for example, the side surfaces SS may be bent from the front surface FS at an angle equal to or greater than 90 degrees and less than 180 degrees. When the front surface FS has a rectangular shape when viewed from the top, the side surfaces SS may include a first side surface SS1 and a third side surface SS3 extended from the front surface FS toward one side and the opposite side in the first direction DR1, respectively, and may include a second side surface SS2 and a fourth side surface SS4 extended toward one side and the opposite side in the second direction DR2, respectively. The first to fourth side surfaces SS1, SS2, SS3 and SS4 may have substantially the same function or configuration except for their positions.

Each of the side surfaces SS: SS1, SS2, SS3 and SS4 may have, but is not limited to, a rounded shape when viewed from the top. In an embodiment, for example, the first side surface SS1 may include rounded shapes on one side and the opposite side in the second direction DR2, respectively. It is, however, to be understood that the present disclosure is not limited thereto.

The first to fourth side surfaces SS1, SS2, SS3 and SS4 may be extended from the front surface FS to have predetermined curvatures and may have a round shape. The first to fourth side surfaces SS1, SS2, SS3 and SS4 may have a convex shape toward the outside of the display device 10. In an embodiment, for example, the first side surface SS1 may include a first curvature, and the second side surface SS2 may include a second curvature. The third side surface SS3 may include a third curvature, and the fourth side surface SS4 may include a fourth curvature. The first to fourth curvatures may be all equal, but the present disclosure is not limited thereto. The first to fourth curvatures may be different from one another, or only some of the first to fourth curvatures may be equal to one another in another embodiment.

The portions that are curved outward from the front surface FS of the display device 10 between adjacent side surfaces SS: SS1, SS2, SS3 and SS4 are defined as the corners CS. The first to fourth side surfaces SS1, SS2, SS3 and SS4 may be spaced apart from each other with a predetermined distance at some positions. The corners CS: CS1, CS2, CS3 and CS4 may be located at the positions where the first to fourth side surfaces SS1, SS2, SS3 and SS4 are spaced apart from each other.

In an embodiment, for example, a first corner CS1 may be disposed between the first side surface SS1 and the second side surface SS2, a second corner CS2 may be disposed between the second side surface SS2 and the third side surface SS3, a third corner CS3 may be disposed between the third side surface SS3 and the fourth side surface SS4, and a fourth corner CS4 may be disposed between the fourth side surface SS4 and the first side surface SS1. The corners CS1, CS2, CS3 and CS4 may have substantially the same function or configuration except for their positions.

The first to fourth corners CS1, CS2, CS3 and CS4 all may include the curvatures of adjacent side surfaces and may have a round shape. In an embodiment, for example, the first corner CS1 may be located between the first side surface SS1 and the second side surface SS2. In this instance, the first corner CS1 may have a double curvature including the first curvature of the first side surface SS1 and the second curvature of the second side surface SS2. The foregoing description on the first corner CS1 may also be applied to the second to fourth corners CS2, CS3 and CS4.

Pixels may be disposed at the corners CS as well as the front surface FS and the side surfaces SS of the display device 10, and images can be displayed at the corners CS. Accordingly, when a user views the display device 10 from the front, the user can recognize that images are displayed on the entire areas of the display device 10. In other words, the user may recognize as if there is substantially no bezel and can experience more immersive contents.

No image may be displayed in the non-display area NDA. The non-display area NDA may include no pixels or emission areas. In the non-display area NDA, signal lines or scan driver for driving the pixels or the emission areas may be disposed. The non-display area NDA may surround the display area DA. The non-display area NDA may be disposed outside the front surface FS and side surfaces SS and outside the corners CS. The non-display area NDA may form the bezel of the display device 10.

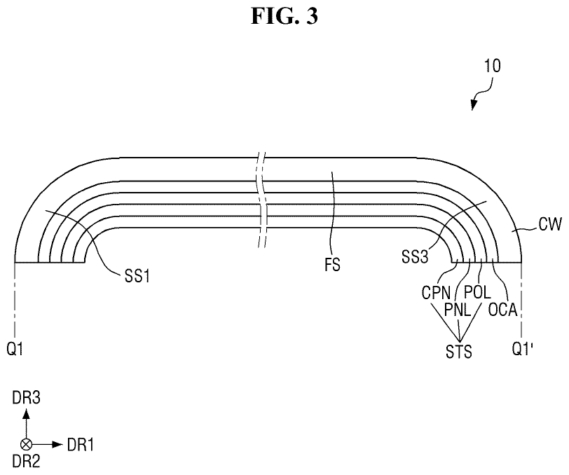

FIG. 3 is a cross-sectional view showing an example of the display panel taken along line Q1-Q1′ of FIG. 2.

Referring to FIG. 3, the display device 10 may include a cover panel CPN, a display panel PNL, a polarizing member POL, an optical adhesive member OCA, and a cover window CW.

The display panel PNL may include a display layer disposed on a substrate. The display layer may include a display area and a non-display area. In the display area of the display layer, emission areas may be located as well as scan lines, data lines, voltage lines, etc. for driving the light-emitting elements. In the non-display area of the display layer, a scan driver circuit outputting scan signals to the scan lines, fan-out lines connecting the data lines with driver circuits, etc. may be disposed.

The display layer may include a pixel circuit layer in which thin-film transistors to be described later are formed, an emission material layer in which light-emitting elements emitting lights are disposed in the emission areas, and an encapsulation layer for encapsulating the emission material layer.

The polarizing member POL may be disposed on the display panel PNL. The polarizing member POL can reduce reflection of external light. The polarizing member POL may be attached to a display surface (or top surface) of the display panel PNL through an adhesive layer.

The optical adhesive member OCA may be disposed on the polarizing member POL. The optical adhesive member OCA may be an adhesive member that attaches the display panel PNL to the cover window CW. In an embodiment, for example, the optical adhesive member OCA may be an optically clear adhesive.

The cover window CW may be disposed on the optical adhesive member OCA. The cover window CW may be attached on the polarizing member POL through the optical adhesive member OCA. The cover window CW may be either an inorganic material such as glass or an organic material such as plastic and polymer material. The cover window CW may include the front surface FS, the side surfaces SS: SS1, SS2, SS3 and SS4, and the corners CS: CS1, CS2, CS3 and CS4.

The cover panel CPN protects the lower surface of the display panel PNL from the outside environment and can maintain the shape of the display panel PNL. In an embodiment, for example, the cover panel CPN may include at least one of a metal plate or a polymer film.

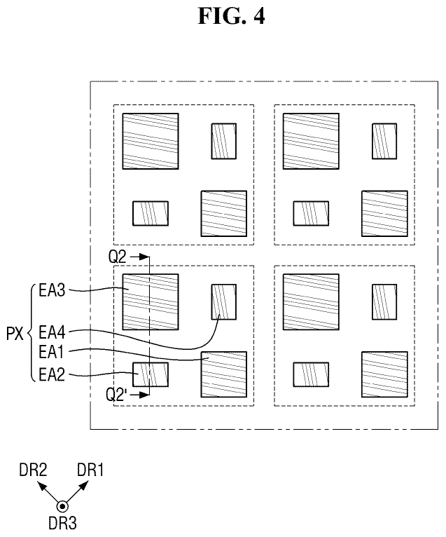

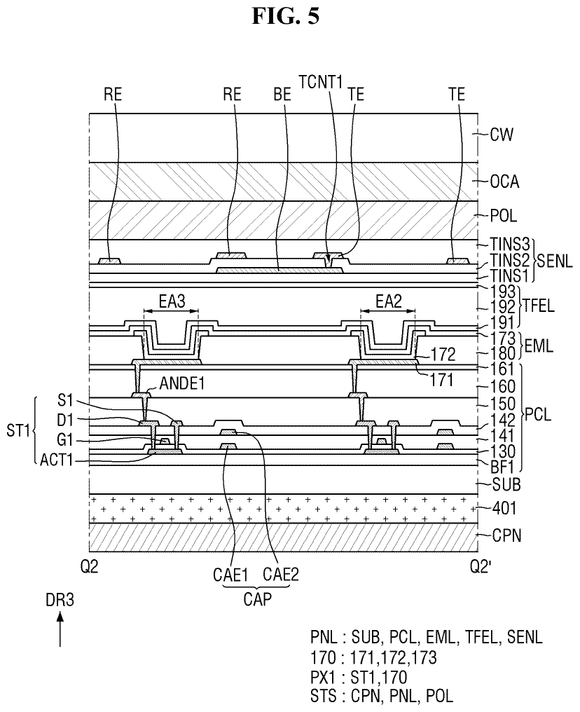

FIG. 4 is a plan view schematically showing pixels of the display area of the display device according to the embodiment. FIG. 5 is a cross-sectional view taken along line Q2-Q2′ of FIG. 4.

Referring to FIG. 4, the display area DA of the display panel 300 may include a plurality of pixels PX. Each of the pixels PX may include a plurality of emission areas EA1, EA2, EA3 and EA4. In an embodiment, for example, each of the pixels PX may include a first emission area EA1, a second emission area EA2, a third emission area EA3, and a fourth emission area EA4. The first emission area EA1, the second emission area EA2, the third emission area EA3 and the fourth emission area EA4 may emit lights of different colors. It should be understood, however, that the present disclosure is not limited thereto. For another example, the first emission area EA1 may emit light of red color, the third emission area EA3 may emit light of blue color, and the second emission area EA2 and the fourth emission area EA4 may emit light of green color.

The cross-sectional structure of a pixel PX will be described with reference to FIG. 5. A coupling layer 401 may be disposed on the cover panel CPN, and the display panel PNL may be disposed on the coupling layer 401. The display panel PNL may include a pixel circuit layer PCL, an emission material layer EML and an encapsulation layer TFEL sequentially disposed on the substrate SUB, and may include a sensor layer SENL including driving electrodes TE, sensing electrodes RE and touch bridge electrodes BE disposed on the encapsulation layer TFEL.

The cover panel CPN may protect the lower surface of the display panel PNL from the outside environment and can help maintain the shape of the display panel PNL.

The coupling layer 401 may attach the cover panel CPN to another element. Therefore, the coupling layer 401 may be made of a material that can attach to the cover panel CPN, and the lower surface of the coupling layer 401 may be in direct contact with and attached to the top surface of the cover panel CPN. The coupling layer 401 may be an adhesive layer or a detachable layer. The coupling layer 401 may include, but is not limited to, an optically clear material made of silicon, such as silicon-based optically clear adhesive.

The substrate SUB may be made of an insulating material such as a polymer resin and glass. In an embodiment, for example, the substrate SUB may include polyimide. In such case, the substrate SUB may be a flexible substrate that can be bent, folded, or rolled. The substrate SUB may provide a space in which other elements disposed thereon can be positioned, and may support the other elements disposed thereon.

The pixel circuit layer PCL may be disposed on the substrate SUB. The pixel circuit layer PCL may include first thin-film transistors ST1. The pixel circuit layer PCL may include a first thin-film transistor ST1, a pixel connection electrode ANDE1, a buffer layer BF1, a gate insulator 130, a first interlayer dielectric layer 141, a second interlayer dielectric layer 142, a first planarization layer 150, and a second planarization layer 160.

The buffer layer BF1 may be disposed on the substrate SUB. The buffer layer BF1 may be formed of or include a silicon nitride layer, a silicon oxynitride layer, a silicon oxide layer, a titanium oxide layer, or an aluminum oxide layer.

The first thin-film transistor ST1 may be disposed on the buffer layer BF1. The first thin-film transistor ST1 may include a first active layer ACT1, a first gate electrode G1, a first source electrode S1, and a first drain electrode D1.

The first active layer ACT1 of the first thin-film transistor ST1 may be disposed on the buffer layer BF1. The first active layer ACT1 may include silicon semiconductor such as polycrystalline silicon, monocrystalline silicon, low-temperature polycrystalline silicon and amorphous silicon. The portion of the first active layer ACT1 overlapping the first gate electrode G1 in the third direction DR3 may be defined as a channel region. Another portion of the first active layer ACT1 not overlapping the first gate electrode G1 in the third direction DR3 may be defined as a conductive region. The conductive regions of the first active layer ACT1 may have conductivity by doping a silicon semiconductor with ions or impurities.

The gate insulator 130 may be disposed on the first active layer ACT1 of the first thin-film transistor ST1. The gate insulator 130 may be formed of or include an inorganic layer, for example, a silicon nitride layer, a silicon oxynitride layer, a silicon oxide layer, a titanium oxide layer, or an aluminum oxide layer.

The first gate electrode G1 of the first thin-film transistor ST1 and a first capacitor electrode CAE1 may be disposed on the gate insulator 130. The first gate electrode G1 of the first thin-film transistor ST1 may overlap the first active layer ACT1 in the third direction DR3. The first capacitor electrode CAE1 may overlap the second capacitor electrode CAE2 in the third direction (z-axis direction). The first gate electrode G1 and the capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric layer 141 may be disposed on the first gate electrode G1 and the first capacitor electrode CAE1. The first interlayer dielectric layer 141 may be formed of or include an inorganic layer, for example, a silicon nitride layer, a silicon oxynitride layer, a silicon oxide layer, a titanium oxide layer, or an aluminum oxide layer. The first interlayer dielectric layer 141 may include a number of inorganic layers.

The second capacitor electrode CAE2 may be disposed on the first interlayer dielectric layer 141. The second capacitor electrode CAE2 may overlap the first capacitor electrode CAE1 in the third direction DR3. Since the first interlayer dielectric layer 141 has a predetermined dielectric constant, a capacitor can be formed by the first capacitor electrode CAE1, the second capacitor electrode CAE2 and the first interlayer dielectric layer 141. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be disposed over the second capacitor electrode CAE2. The second interlayer dielectric layer 142 may be formed of or include an inorganic layer, for example, a silicon nitride layer, a silicon oxynitride layer, a silicon oxide layer, a titanium oxide layer, or an aluminum oxide layer.

The first source electrode S1 and the first drain electrode D1 of the first thin-film transistor ST1 may be disposed on the second interlayer dielectric layer 142. The first source electrode S1 and the first drain electrode D1 may be made up of a single layer of one of molybdenum (Mo), aluminum (Al), chromium (Cr), gold (Au), titanium (Ti), nickel (Ni), neodymium (Nd) and copper (Cu) or an alloy thereof, or multiple layers thereof.

The first source electrode S1 of the first thin-film transistor ST1 may be connected to the conductive region located on a side of the channel region of the first active layer ACT1 through a contact hole penetrating through the gate insulator 130, the first interlayer dielectric layer 141 and the second interlayer dielectric layer 142. The first drain electrode D1 of the first thin-film transistor ST1 may be connected to the conductive region located on the opposite side of the change region of the first active layer ACT1 through a contact hole penetrating through the gate insulator 130, the first interlayer dielectric layer 141 and the second interlayer dielectric layer 142.

The first planarization layer 150 may be disposed on the first source electrode S1 and the first drain electrode D1 to provide a flat surface over the thin-film transistors having different levels. The first planarization layer 150 may be formed of or include an organic layer such as an acryl resin, an epoxy resin, a phenolic resin, a polyamide resin and a polyimide resin.

The pixel connection electrode ANDE1 may be disposed on the first planarization layer 150. The pixel connection electrode ANDE1 may be connected to the first source electrode S1 or the first drain electrode D1 of the first thin-film transistor ST1 through a contact hole penetrating the first planarization layer 150. The pixel connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization layer 160 may be disposed on the pixel connection electrode ANDE1. The second planarization layer 160 may be formed of or include an organic layer such as an acryl resin, an epoxy resin, a phenolic resin, a polyamide resin and a polyimide resin.

A barrier layer 161 may be disposed on the second planarization layer 160. The barrier layer 161 may be formed of or include a silicon nitride layer, a silicon oxynitride layer, a silicon oxide layer, a titanium oxide layer, or an aluminum oxide layer.

The emission material layer EML may be disposed on the pixel circuit layer PCL. The emission material layer EML may include light-emitting elements 170 and a bank 180.

Each of the light-emitting elements 170 may include a pixel electrode 171, an emissive layer 172, and a common electrode 173. In each of the emission areas EA1, EA2, E3 and E4, the pixel electrode 171, the emissive layer 172 and the common electrode 173 are stacked on one another sequentially, so that holes from the pixel electrode 171 and electrons from the common electrode 173 are combined with each other in the emissive layer 172 to emit light. In such case, the pixel electrode 171 may be an anode electrode while the common electrode 173 may be a cathode electrode. The first emission area EA1 and the fourth emission area EA4 may be substantially identical to the third emission area EA3.

The pixel electrode 171 may be disposed on the barrier layer 161. The pixel electrode 171 may be connected to the pixel connection electrode ANDE1 through a contact hole penetrating the barrier layer 161 and the second planarization layer 160.

In a top-emission structure in which light is emitted toward the common electrode 173 from the emissive layer 172, the pixel electrode 171 may be made up of a stack structure (ITO/Al/ITO) of ITO having a high work function, aluminum for reflecting light, and ITO with high adhesion.

The bank 180 serves to define each of the emission areas E1, E2, E3 and E4 of display pixels. To this end, the bank 180 may be disposed on the barrier layer 161 to expose a portion of the pixel electrode 171. The bank 180 may cover the edge of the pixel electrode 171. The bank 180 may be formed of or include an organic layer such as an acryl resin, an epoxy resin, a phenolic resin, a polyamide resin and a polyimide resin.

The emissive layer 172 may be disposed on the pixel electrode 171. The emissive layer 172 may include an organic material to emit light of a certain color. In an embodiment, for example, the emissive layer 172 may include a hole transporting layer, an organic material layer, and an electron transporting layer. The organic material layer may include a host and a dopant. The organic material layer may include a material that emits a predetermined light, and may be formed using a phosphor or a fluorescent material.

The common electrode 173 may be disposed on the emissive layer 172. The common electrode 173 may cover the emissive layer 172. The common electrode 173 may be a common layer formed across the display pixels. A capping layer may be disposed on the common electrode 173.

In the top-emission structure, the common electrode 173 may reduce resistance, and may be formed with a thin alloy of a transparent conductive material (TCP) such as ITO and IZO that can transmit light, and magnesium (Mg), silver (Ag), or an alloy of magnesium (Mg) and silver (Ag) with a low work function.

The encapsulation layer TFEL may be disposed on the emission material layer EML. The encapsulation layer TFEL may include at least one inorganic layer to prevent permeation of oxygen or moisture into the emission material layer EML. In addition, the encapsulation layer TFEL may include at least one organic layer to protect the emission material layer EML from particles.

In an embodiment, for example, the thin-film encapsulation layer TFEL may include a first inorganic encapsulation film 191 disposed on the common electrode 173, an organic encapsulation film 192 disposed on the first inorganic encapsulation film 191, and a second inorganic encapsulation film 193 disposed on the organic encapsulation film 192. The first inorganic encapsulation film 191 and the second inorganic encapsulation film 193 may be made up of multiple films in which one or more inorganic layers of a silicon nitride layer, a silicon oxynitride layer, a silicon oxide layer, a titanium oxide layer and an aluminum oxide layer are alternately stacked on one another. The organic layer may be an acryl resin, an epoxy resin, a phenolic resin, a polyamide resin or a polyimide resin.

The sensor layer SENL may be disposed on the encapsulation layer TFEL. The sensor layer SENL may include the driving electrodes TE, the sensing electrodes RE and the touch connection electrodes BE.

A first touch inorganic film TINS1 may be disposed on the encapsulation layer TFEL. The first touch inorganic film TINS1 may be formed as a silicon nitride layer, a silicon oxynitride layer, a silicon oxide layer, a titanium oxide layer, or an aluminum oxide layer.

The touch bridge electrodes BE may be disposed on the first touch inorganic film TINS1. The touch connection electrodes BE may be formed of or include a stacked structure of aluminum and ITO (ITO/AI/ITO).

A second touch inorganic layer TINS2 may be disposed on the touch connection electrodes BE. The second touch inorganic layer TINS2 may be formed as a silicon nitride layer, a silicon oxynitride layer, a silicon oxide layer, a titanium oxide layer, or an aluminum oxide layer.

The driving electrodes TE and the sensing electrodes RE may be disposed on the second touch inorganic layer TINS2. In order to prevent the light emitted from the emission areas EA1, EA2, EA3 and EA4 from being blocked by the driving electrodes TE and the sensing electrodes RE to thereby decrease the luminance of the light, the driving electrodes TE and the sensor electrodes RE do not overlap the emission areas EA1, EA2, EA3 and EA4 in a plan view. The driving electrodes TE and the sensing electrodes RE may be formed of or include a stack structure of aluminum and titanium (Ti/Al/Ti).

A touch organic film TINS3 may be disposed on the driving electrodes TE and the sensing electrodes RE. The touch organic film TINS3 may be an acryl resin, an epoxy resin, a phenolic resin, a polyamide resin and a polyimide resin.

The polarizing member POL may be disposed on the display panel PNL. The polarizing member POL may be attached to the display surface of the display panel PNL through the adhesive layer.

An optical coupling member OCA may be disposed on the polarizing member POL, and the cover window CW may be disposed on the optical coupling member OCA. The cover window CW may be attached to the display panel PNL through the optical coupling member OCA disposed between the display panel PNL and the cover window CW. The optical coupling member OCA may include an acrylic resin. Accordingly, the optical coupling member OCA may be optically clear. The upper surface of the optical coupling member OCA may be in direct contact with the lower surface of the cover window CW.

As described above, the display device 10 may include the side surfaces and the corners having curvatures. The corners of the display device 10 may have a double curvature having both the curvatures of the left and right side surfaces and the curvatures of the upper and lower side surfaces, and accordingly strain may be applied. In the process of attaching the display stack structure STS (e.g., a stack structure from the cover panel to the polarizing member in FIG. 5) to the cover window CW, the display stack structure STS and the cover window CW may be delaminated, i.e., a failure (e.g., buckling failure) may occur at the corners because the corners of the cover window CW have the double curvature. In an embodiment, for example, tensile stress and compressive stress due to the double curvature at the corners are applied to the display stack structure STS at the corners of the cover window CW, and buckling failure occurs if the compression limit of the display stack structure STS is exceeded. In particular, the risk of buckling failure may further increase in high-temperature and high-humidity environments.

Hereinafter, a display device 10 according to an embodiment of the present disclosure that can suppress buckling failure occurring at the corners of the cover window CW is disclosed.

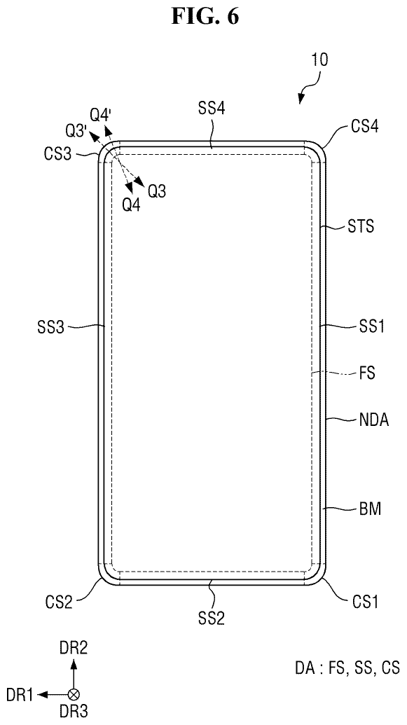

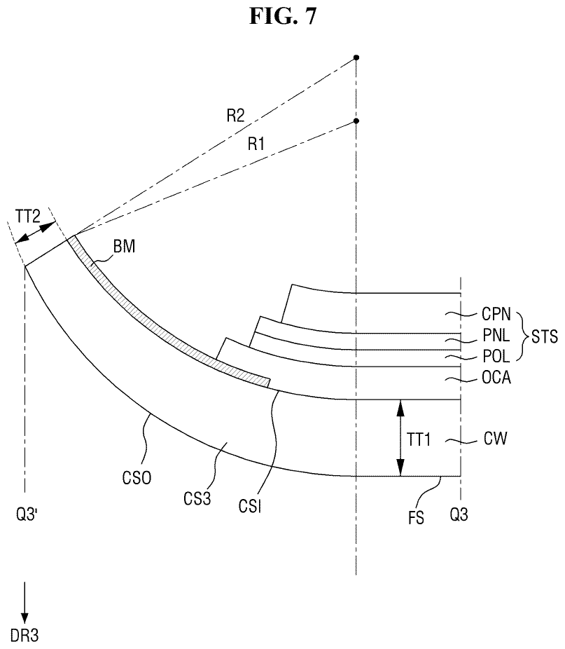

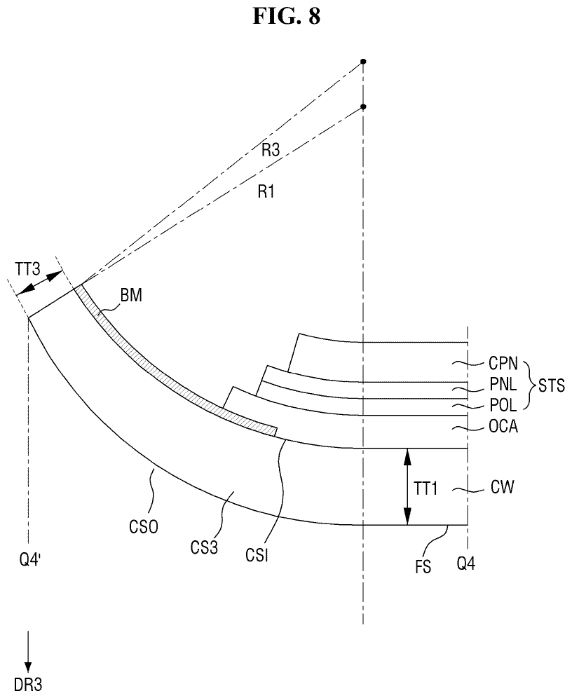

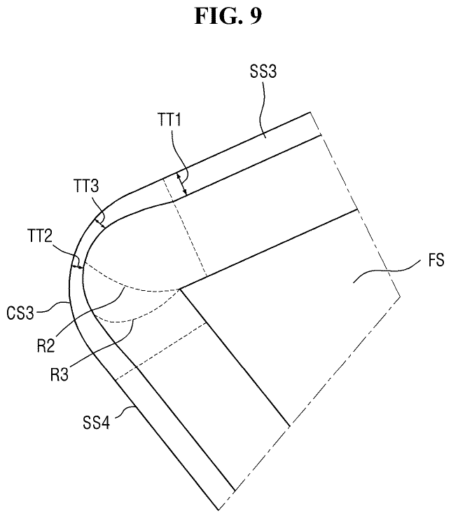

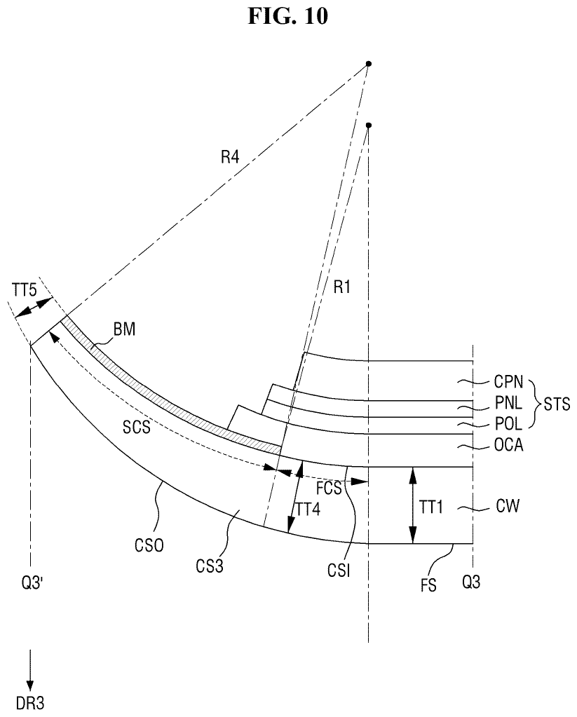

FIG. 6 is a plan view showing a rear side of a display device according to an embodiment. FIG. 7 is a cross-sectional view showing an example of the display device taken along line Q3-Q3′ of FIG. 6. FIG. 8 is a cross-sectional view showing an example of the display device taken along line Q4-Q4′ of FIG. 6. FIG. 9 is a perspective view schematically showing a third corner portion of the display device according to the embodiment. FIG. 10 is a cross-sectional view showing another example of the display device taken along line Q3-Q3′ of FIG. 6.

Referring to FIGS. 6 to 9, the display device 10 according to the embodiment may include a cover window CW including a front surface FS, side surfaces SS: SS1, SS2, SS3 and SS4, corners CS: CS1, CS2, CS3 and CS4. A display stack structure STS having a cover panel CPN, a display panel PNL and a polarizing member POL stacked on one another is attached on the back side (or rear surface) of the cover window CW by an optical adhesive member OCA.

The corners CS: CS1, CS2, CS3 and CS4 of the cover window CW may include an outer surface CSO and an inner surface CSI opposed to the outer surface CSO. The outer surface CSO may be located on the side of the display surface a user watches, while the inner surface CSI may be located on the side where the display stack structure STS is disposed.

A black matrix BM may be disposed on the inner surface CSI of the corners CS: CS1, CS2, CS3 and CS4. The black matrix BM may block or absorb light to prevent reflection or leakage of light at the edges of the display device 10. The black matrix BM may be disposed between the cover window CW and the optical adhesive member OCA, and may be disposed to overlap with the corners CS: CS1, CS2, CS3 and CS4 in a plan view.

According to the embodiment, each of the outer surface CSO and the inner surface CSI of the corners CS: CS1, CS2, CS3 and CS4 may be formed as a curved surface with a predetermined radius of curvature. According to an embodiment of the present disclosure, a first radius R1 of curvature of the outer surface CSO of the corners CS: CS1, CS2, CS3 and CS4 may be smaller than a second radius R2 of curvature of the inner surface CSI.

Referring to FIGS. 7 to 9, the third corner CS3 will be described as an example. FIG. 7 shows a portion cut at the angle of 45 degrees with respect to the extension direction (i.e., first direction DR1) of the fourth side surface SS4, while the angle between the third side surface SS3 and the fourth side surface SS4 is 90 degrees. FIG. 8 shows a portion cut at the angle of 70 degrees with respect to the extension direction (i.e., first direction DR1) of the fourth side surface SS4, while the angle between the third side surface SS3 and the fourth side surface SS4 is 90 degrees.

The first radius R1 of curvature of the outer surface CSO and the second radius R2 of curvature of the inner surface CSI of the third corner CS3 may start from the front surface FS of the cover window CW. The first radius R1 of curvature of the outer surface CSO of the third corner CS3 may be smaller than the second and third radii R2 and R3 of curvature of the inner surface CSI. The thickness of the cover window CW may be generally constant in all areas, but according to this embodiment, the inner surface CSI of the corners CS: CS1, CS2, CS3 and CS4 of the cover window CW may be shaved off. As a result, the second and third radii R2 and R3 of curvature of the inner surface CSI of the corners CS: CS1, CS2, CS3 and CS4 may be greater than the first radius R1 of curvature of the outer surface CSO.

As described above, the corners CS: CS1, CS2, CS3 and CS4 have the double curvature having the left-and-right surface curvature as well as the upper-and-lower surface curvature, so that compressive stress acts on the display stack structure STS. According to this embodiment, the inner surface CSI of the corners CS: CS1, CS2, CS3 and CS4 of the cover window CW where the display stack structure STS is attached may be shaved off to increase the radius of curvature of the inner surface. In this manner, it is possible to suppress buckling failure by reducing compressive stress applied to the display stack structure STS.

The third corner CS3 is still described as an example. The second radius R2 of curvature of the inner surface CSI may be the largest at the position at the angle of 45 degrees in the third corner CS3 with respect to the extension direction (i.e., first direction DR1) of the fourth side surface SS4, while the angle between the third side surface SS3 and the fourth side surface SS4 is 90 degrees. On the contrary, the radius of curvature of the inner surface CSI may be the smallest at the boundary between the third side surface SS3 and the third corner CS3 and at the boundary between the fourth side surface SS4 and the third corner CS3 in the third corner CS3. The radius of curvature of the inner surface CSI at the boundary between the third side surface SS3 and the third corner CS3 and at the boundary between the fourth side surface SS4 and the third corner CS3 may be substantially equal to the first radius R1 of curvature of the outer surface CSO.

According to the embodiment of the present disclosure, the radius of curvature of the third corner CS3 may decrease from the position at the angle of 45 degrees with respect to the extension direction (i.e., first direction DR1) of the fourth side surface SS4 to the boundary between the third side surface SS3 and the third corner CS3, and to the boundary between the fourth side surface SS4 and the third corner CS3.

In an embodiment, for example, as shown in FIG. 7, the second radius R2 of curvature of the inner surface CSI of the third corner CS3 may be the largest at the position at the angle of 45 degrees with respect to the extension direction (i.e., first direction DR1) of the fourth side surface SS4 while the angle between the third side surface SS3 and the fourth side surface SS4 is 90 degrees. In addition, as shown in FIG. 8, the third radius R3 of curvature of the inner surface CSI of the third corner CS3 at the position adjacent to the boundary between the fourth side surface SS4 and the third corner CS3, i.e., at the position at the angle of 70 degrees with respect to 90 degrees, which is the angle between the third side surface SS3 and the fourth side surface SS4 may be smaller than the second radius R2 of curvature of the inner surface CSI of the third corner CS3.

Accordingly, the inner surface CSI with a radius of curvature that gradually decreases from the position of the third corner CS3 at the 45 degree toward the outside of the third corner CS3 may be connected to the fourth side surface SS4 and the third side surface SS3 smoothly.

In addition, the corners CS: CS1, CS2, CS3 and CS4 may include different portions having different thicknesses. The third corner CS3 will be described as an example. The thickness of the third corner CS3 may decrease away from the front surface FS. In an embodiment, for example, the portion of the third corner CS3 that is closest to the front surface FS may have the greatest thickness, and the portion thereof closest to the side of the cover window CW may have the smallest thickness.

As shown in FIGS. 7 to 9, the front surface FS of the cover window CW has a first thickness TT1, and the sides of the third corner CS3 of the cover window CW may have a second thickness TT2 and a third thickness TT3. The thickness of the third corner CS3 may gradually decrease from the first thickness TT1 to the second thickness TT2 or the third thickness TT3. That is to say, the thickness of the third corner CS3 may range from the second thickness TT2 to the first thickness TT1 or from the third thickness TT3 to the first thickness TT1.

The thickness of the third corner CS3 may increase from the position at the angle of 45 degrees with respect to the extension direction (i.e., first direction DR1) of the fourth side surface SS4 to the boundary between the third side surface SS3 and the third corner CS3, and to the boundary between the fourth side surface SS4 and the third corner CS3.

In an embodiment, for example, as shown in FIG. 7, the second thickness TT2 of the third corner CS3 may be the smallest at the position at the angle of 45 degrees with respect to the extension direction (i.e., first direction DR1) of the fourth side surface SS4 while the angle between the third side surface SS3 and the fourth side surface SS4 is 90 degrees. In addition, as shown in FIG. 8, the third thickness TT3 of the third corner CS3 at the position adjacent to the boundary between the fourth side surface SS4 and the third corner CS3, i.e., at the position at the angle of 70 degrees with respect to 90 degrees, which is the angle between the third side surface SS3 and the fourth side surface SS4 may be larger than the second thickness TT2.

Accordingly, as shown in FIG. 9, the thickness that gradually increases from the position of the third corner CS3 at the 45 degree toward the outside of the third corner CS3 may be connected to the thicknesses of the fourth side surface SS4 and the third side surface SS3 smoothly.

As described above, according to this embodiment, the inner surface CSI of the corners CS: CS1, CS2, CS3 and CS4 of the cover window CW where the display stack structure STS is attached may be shaved off to reduce the thickness. In this manner, it is possible to suppress buckling failure by reducing compressive stress applied to the display stack structure STS.

Referring to FIG. 10 showing another example of the third corner CS3, the inner surface CSI of the third corner CS3 may include a first inner surface FCS and a second inner surface SCS. The first inner surface FCS of the third corner CS3 may be adjacent to the front surface FS while the second inner surface SCS thereof may be adjacent to the side of the cover window CW. In other words, the first inner surface FCS of the third corner CS3 may not overlap with the black matrix BM while the second inner surface SCS thereof may overlap with the black matrix BM in a plan view.

The first inner surface FCS of the third corner CS3 may have the first radius R1 of curvature equal to the radius of the outer surface CSO, and the second inner surface SCS of the third corner CS3 may have a fourth radius R4 of curvature of the second inner surface SCS. As the first inner surface FCS of the third corner CS3 has the same first radius R1 of curvature as the outer surface CSO, the fourth thickness TT4 between the first inner surface FCS and the outer surface CSO is constant and may be equal to the first thickness TT1 of the front surface FS.

The fourth radius R4 of curvature of the second inner surface SCS may be larger than the first radius R1 of curvature of the outer surface CSO. The fourth radius R4 may start from one side (i.e., inner side) of the black matrix BM and may be terminated at the other side (i.e., outer side) of the black matrix BM or the side of the cover window CW. As the fourth radius R4 of curvature of the second inner surface SCS is greater than the first radius R1 of curvature of the outer surface CSO, the display stack structure STS is disposed closer to the display surface of the display device 10 at the third corner CS3, so that the difference in visibility between the front surface FS and the corners CS can be effectively reduced.

The thickness of the second inner surface SCS may gradually decrease from the boundary between the first inner surface FCS and the second inner surface SCS toward the outside (e.g., the side of the cover window CW). In an embodiment, for example, the thickness of the second inner surface SCS may range from the fourth thickness TT4 of the first inner surface FCS to the fifth thickness TT5, which is the thickness of the outermost side of the cover window CW. Likewise, the thickness of the second inner surface SCS may increase toward the boundary between the third corner CS3 and the fourth side surface SS4 and the boundary between the third corner CS3 and the third side surface SS3.

Although the first inner surface FCS and the second inner surface SCS are distinguished by the black matrix BM in the example shown in FIG. 10, this is merely illustrative. The boundary between the first inner surface FCS and the second inner surface SCS may overlap with the black matrix BM as long as it overlaps with the display stack structure STS in a plan view.

Hereinafter, display devices according to other embodiments of the present disclosure will be described with reference to other drawings.

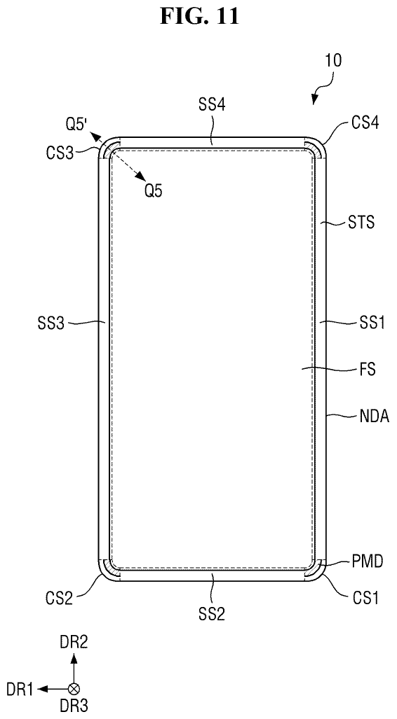

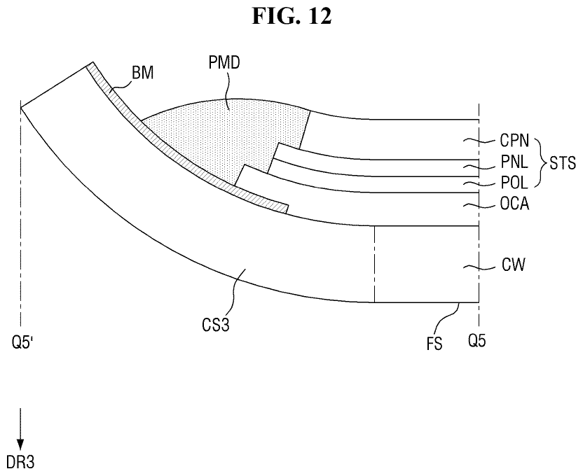

FIG. 11 is a plan view showing an example of a display device to another embodiment of the present disclosure. FIG. 12 is a cross-sectional view taken along line Q5-Q5′ of FIG. 11.

The embodiment of FIGS. 11 and 12 is substantially identical to the above embodiment except that corners CS: CS1, CS2, CS3 and CS4 of a cover window CW have the same thickness and further include a protective member PMD; and, therefore, the redundant descriptions will be omitted.

The corners CS: CS1, CS2, CS3 and CS4 of the cover window CW have the same thickness as the front surface FS, and may have the same radius of curvature.

The display device 10 according to the embodiment may further include a protective member PMD. The protective member PMD may be disposed at the corners CS: CS1, CS2, CS3 and CS4 of the cover window CW. In an embodiment, for example, the protective member PMD may be disposed on the back side (or rear surface) of the cover window CW and may overlap with the corners CS: CS1, CS2, CS3 and CS4 in a plan view.

The protective member PMD may block permeation of moisture from the outside and may attach the cover window CW to the display stack structure STS. The protective member PMD may include a thermosetting resin or UV curing resin that has a moisture-proof feature. In an embodiment, for example, the protective member PMD may include a material with excellent moisture resistance, such as a silicone resin, polyimide and polyethylene terephthalate.

The protective member PMD may have a viscosity of 300 cps or higher for ease of application. In addition, the protective member PMD may further include a dye or pigment that gives black color to the resins.

The protective member PMD may be disposed in an area (i.e., space) defined by the cover window CW and the display stack structure STS. In an embodiment, for example, the space between the rear surface of the cover window CW and the side surface of the display stack structure STS may be filled with the protective member PMD. The protective member PMD may be in direct contact with the upper surface of the black matrix BM and may be in contact with the side surface of the display stack structure CTS. The protective member PMD may be disposed so that it does not overflow onto the rear surface of the display stack structure STS and the side surface of the cover window CW.

According to this embodiment, the protective member PMD may be disposed at the corners CS: CS1, CS2, CS3 and CS4 of the cover window CW. In an embodiment, for example, the protective member PMD may be disposed to overlap with the corners CS: CS1, CS2, CS3 and CS4 of the cover window CW, and may not overlap with the side surfaces SS in a plan view. The display stack structure STS receives stress by the curvature of the cover window CW. As the protective member PMD disposed at the corners CS: CS1, CS2, CS3 and CS4 fixes the display stack structure STS, the stress is distributed to where the protective member PMD is not disposed, so that it is possible to prevent deformation of the display stack structure STS. If the protective member PMD is disposed on the entire side surface of the cover window CW, the stress of the display stack structure STS cannot be distributed, and accordingly deformation may occur.

The protective member PMD may be applied after the cover window CW is attached to the display stack structure STS. The protective member PMD may be applied via a solution process, for example, by dispensing, slit coating, inkjet printing, etc. After having been applied, the protective member PMD may be either heat-cured or UV-cured depending on the material.

The display stack structure STS may have steps on its side to increase the adhesive area with the protective member PMD. In an embodiment, for example, steps may be formed between the optical adhesive member OCA and the display panel PNL and between the display panel PNL and the cover panel CPN. To this end, the area of the optical adhesive member OCA may be larger than the area of the display panel PNL and the area of the display panel PNL may be larger than the area of the cover panel CPN at the corners CS: CS1, CS2, CS3 and CS4 of the cover window CW. The display panel PNL and the polarizing member POL may have the same area. Accordingly, the side surface of the optical adhesive member OCA protrudes outward (e.g., toward the side of the cover window) from the side surface of the display panel PNL and the polarizing member POL, and the side surface of the display panel PNL and the polarizing member POL may protrude outward from the side surface of the cover panel CPN.

The protective member PMD may be in contact with the side surface and a portion of the rear surface of the optical adhesive member OCA, the side surface of the polarizing member POL and the display panel PNL, a portion of the rear surface of the display panel PNL, and the side surface of the cover panel CPN. It should be understood, however, that the present disclosure is not limited thereto. The side surfaces of the display stack structure STS may be aligned with one another without any step in another embodiment.

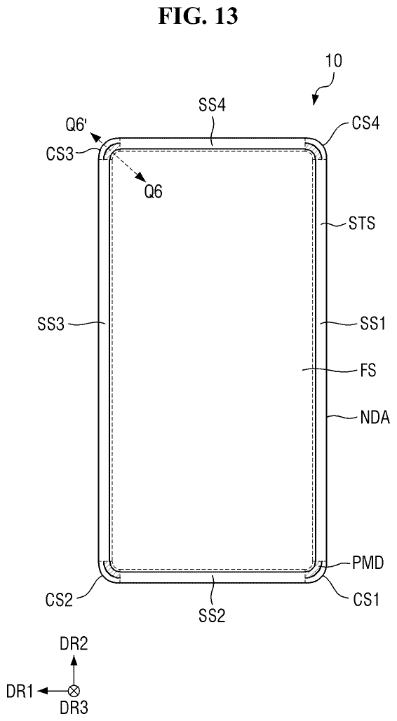

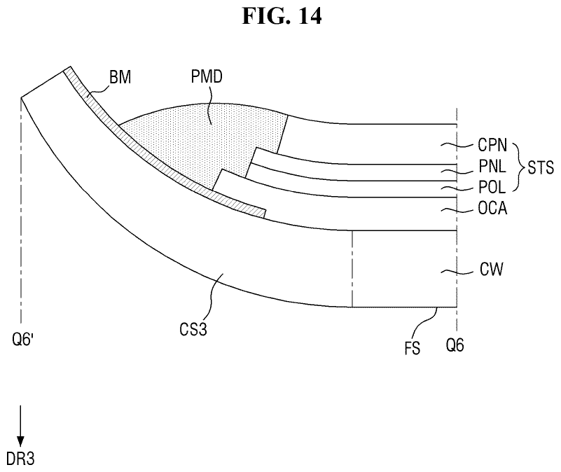

FIG. 13 is a plan view showing an example of a display device to still another embodiment of the present disclosure. FIG. 14 is a cross-sectional view taken along line Q6-Q6′ of FIG. 11.

Referring to FIGS. 13 and 14, this embodiment may include the structure according to the embodiment of FIGS. 6 to 10 as well as the structure according to the embodiment of FIGS. 11 and 12 described above. In an embodiment, for example, the radius of curvature of the outer surface CSO and the radius of curvature of the inner surface CSI of the corners CS: CS1, CS2, CS3 and CS4 of the cover window CW are different from each other, and the thickness may gradually decrease toward the outside. In addition, the protective member PMD may be disposed at the corners CS: CS1, CS2, CS3 and CS4 of the cover window CW.

According to this embodiment, the radius of curvature of the outer surface CSO and the radius of curvature of the inner surface CSI of the corners CS: CS1, CS2, CS3 and CS4 of the cover window CW are different from each other, and the thickness may gradually decrease toward the outside, such that buckling failure can be suppressed. In addition, the protective member PMD may be disposed at the corners CS: CS1, CS2, CS3 and CS4 of the cover window CW, so that deformation of the display stack structure STS can be prevented, and permeation of moisture can be prevented as well.

In particular, according to the embodiment, as the radius of curvature of the inner surface CSI of the corners CS: CS1, CS2, CS3 and CS4 of the cover window CW increases, the area (i.e., space) defined by the cover window CW and the display stack structure STS may become larger. That is to say, as the volume of the area where the protective member PMD is applied increases, the amount of the protective member PMD may increase, so that it is possible to further prevent the permeation of moisture as well as deformation of the display stack structure STS. Accordingly, the reliability of the display device 10 in a high-temperature and high-humidity environment can be increased.

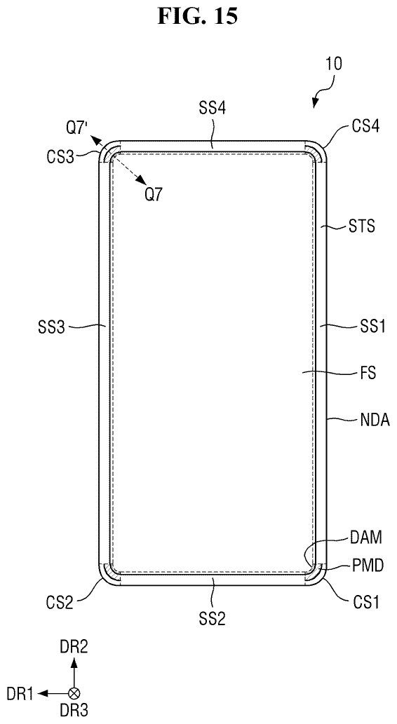

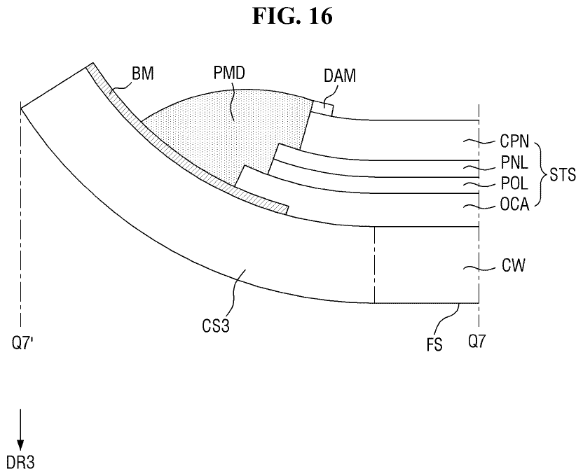

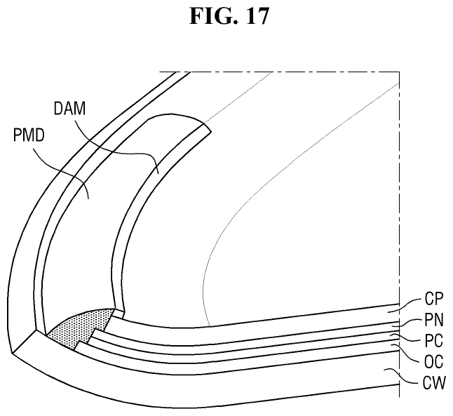

FIG. 15 is a plan view showing an example of a display device to yet another embodiment of the present disclosure. FIG. 16 is a cross-sectional view taken along line Q7-Q7′ of FIG. 16. FIG. 17 is a rear perspective view schematically showing a third corner of a cover window.

The embodiment of FIGS. 15 to 17 is different from the above-described embodiment of FIGS. 13 and 14 in that a dam DAM is further disposed on the rear surface of a display stack structure STS.

The display device 10 according to the embodiment may include a dam DAM disposed on a surface of the display stack structure STS.

The dam DAM may be disposed on a portion of the rear surface of the cover panel CPN of the display stack structure STS. The dam DAM may overlap with the corners CS: CS1, CS2, CS3 and CS4 of the cover window CW when viewed from the top (i.e., in a plan view). In addition, the dam DAM may be disposed associated with the protective member PMD. In an embodiment, for example, the number of the dams DAM may be equal to the number of the protective members PMD.

The dam DAM may serve to prevent the protective member PMD from overflowing onto the rear surface of the display stack structure STS and increase the amount of the applied protective member PMD. In other words, the dam DAM can increase the amount of the protective member PMD by increasing the volume of the area where the protective e member PMD is applied. The protective member PMD may be in contact with the side of the dam DAM but not with the upper surface of the dam DAM.

The dam DAM may be disposed on a portion of the rear surface of the cover panel CPN, e.g., at the end of the cover panel CPN that overlaps with the corners CS: CS1, CS2, CS3 and CS4 of the cover window CW in a plan view. The side of the dam DAM may be aligned and coincide with the side of the cover panel CPN. It should be understood, however, that the present disclosure is not limited thereto. The dam DAM may be disposed at a certain distance from the end of the cover panel CPN in another embodiment. In this instance, the protective member PMD can be applied to the rear surface of the cover panel CPN, increasing the adhesive area between the protective member PMD and the display stack structure STS and increasing the amount of protective member PMD.

The dam DAM may be made of a resin, and may be applied in the form of paste and then cured, or may be attached in the form of a film. The resin may include, for example, polyethylene terephthalate (PET), polyimide (PI), poly thiourethane (PTU), etc. The thickness of the dam DAM is not particularly limited unless the overall thickness of the display device 10 is too thick.

As described above, the display device 10 according to the embodiment includes the dam DAM on the rear surface of the display stack structure STS, and accordingly the amount of the protective member PMD can be increased, so that it is possible to protect the display device 10 from permeation of moisture and to prevent deformation of the display stack structure STS.

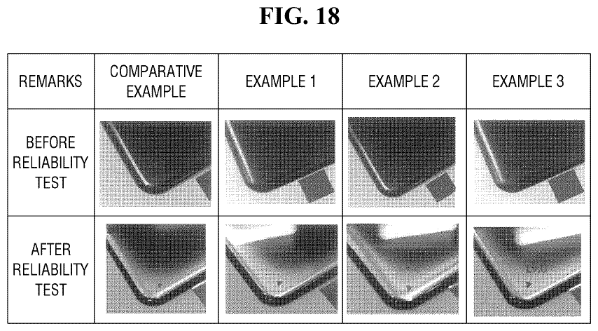

FIG. 18 is a table showing results of the reliability test of display devices. FIG. 18 shows images of corners of display devices before and after the reliability test. In FIG. 18, the levels of buckling failure were determined with the naked eyes. The lower the levels are, the lower the degrees of buckling failure are. The reliability test was conducted for twenty-four hours at the temperature of 85° C. and the humidity of 85%.

Comparative Example shows a display device having a structure in which the inner and outer surfaces of the cover window have the same radius of curvature. Example 1 is the embodiment shown in FIGS. 6 to 10 and shows a display device having the structure in which the radius of curvature of the inner surface of the corners of the cover window is increased than the radius of curvature of the outer surface. Example 2 is the embodiment shown in FIGS. 11 and 12 and shows a display device having the structure in which the protective member is applied at the corners of the cover window. Example 3 is the embodiment shown in FIGS. 13 and 14 and shows a display device having the structure in which the radius of curvature of the inner surface of the corners of the cover window is increased than the radius of curvature of the outer surface, and the protective member is applied.

Referring to FIG. 18, the display device according to Comparative Example exhibited Lv.4 buckling failure after the reliability test. The display device according to Example 1 exhibited Lv.3 buckling failure after the reliability test. The display device according to Example 2 exhibited Lv.2 buckling failure after the reliability test. The display device according to Example 3 exhibited Lv.0 buckling failure, i.e., no failure after the reliability test.

It can be seen from the results that Examples 1 to 3 had improved reliability compared to Comparative Example. In particular, no buckling defects were observed in Example 3, which implies that the reliability is excellent.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display stack structure comprising at least a display panel;
an optical adhesive member disposed on a surface of the display stack structure; and
a cover window disposed on a surface of the optical adhesive member opposed to the display stack structure,
wherein the cover window comprises a front surface, a first side surface extended from the front surface in a first direction and having a curvature, a second side surface extended from the front surface in a second direction intersecting the first direction and having a curvature, and a corner located between the first side surface and the second side surface and having the curvature of the first side surface and the curvature of the second side surface,
wherein the cover window comprises an inner surface adjacent to the display stack structure and an outer surface opposed to the inner surface, and
wherein the outer surface of the cover window has a first radius of curvature, and the inner surface of the cover window has a second radius of curvature greater than the first radius of curvature at the corner.

2. The display device of claim 1, wherein an entirety of the outer surface of the cover window has the first radius of curvature at the corner.

3. The display device of claim 1, wherein the second radius of curvature of the inner surface gradually decreases toward the first side surface or the second side surface at the corner.

4. The display device of claim 3, wherein the second radius of curvature is largest at a position at 45 degrees with respect to the first direction at the corner.

5. The display device of claim 4, wherein the second radius of curvature gradually decreases toward the first side surface or the second side surface from the position at 45 degrees with respect to the first direction at the corner.

6. The display device of claim 1, wherein a thickness of the cover window gradually decreases from the front surface to a side of the cover window opposed to the front surface at the corner.

7. The display device of claim 1, wherein a thickness of the cover window gradually increases toward the first side surface or the second side surface from the position at 45 degrees with respect to the first direction at the corner.

8. The display device of claim 7, wherein the thickness of the cover window is smallest at the position at 45 degrees with respect to the first direction at the corner.

9. The display device of claim 7, further comprising:
a black matrix disposed between the cover window and the optical adhesive member,
wherein the black matrix overlaps with the first side surface, the second side surface and the corner but does not overlap with the front surface in a plan view.

10. The display device of claim 9, wherein the inner surface of the cover window comprises a first inner surface that does not overlap with the black matrix and a second inner surface that overlaps with the black matrix at the corner in the plan view, and
wherein a radius of curvature of the first inner surface is equal to the first radius of curvature, and a radius of curvature of the second inner surface is greater than the first radius of curvature.

11. The display device of claim 1, further comprising:
a protective member disposed in a space defined by the cover window and the display stack structure,
wherein the protective member overlaps with the corner of the cover window in a plan view.

12. The display device of claim 11, wherein the protective member comprises one of a silicone resin, polyimide, and polyethylene terephthalate.

13. The display device of claim 11, further comprising:
a dam disposed on a rear surface of the display stack structure,
wherein the dam overlaps with the corner of the cover window in the plan view.

14. The display device of claim 11, wherein the display stack structure further comprises:
a cover panel disposed on a first surface of the display panel; and
a polarizing member disposed on a second surface of the display panel opposed to the first surface,
wherein a side surface of the optical adhesive member protrudes outward from a side surface of the polarizing member and the display panel, and the side surface of the polarizing member and the display panel protrudes outward from a side surface of the cover panel in the plan view.

15. A display device comprising:
a display stack structure comprising at least a display panel;
an optical adhesive member disposed on a surface of the display stack structure;
a cover window disposed on a surface of the optical adhesive member opposed to the display stack structure; and
a protection member disposed in a space defined by the cover window and the display stack structure,
wherein the cover window comprises
a front surface, a first side surface extended from the front surface in a first direction and having a curvature, a second side surface extended from the front surface in a second direction intersecting the first direction and having a curvature, and a corner located between the first side surface and the second side surface and having the curvature of the first side surface and the curvature of the second side surface,
wherein the cover window comprises an inner surface adjacent to the display stack structure and an outer surface opposed to the inner surface, and
wherein the protective member overlaps with the corner of the cover window but does not overlap with the front surface, the first side surface and the second side surface in a plan view.

16. The display device of claim 15, further comprising:
a black matrix disposed between the cover window and the optical adhesive member and overlapping with the corner in the plan view,
wherein the protective member is in contact with the black matrix and side surfaces of the display stack structure.

17. The display device of claim 15, wherein the protective member comprises one of a silicone resin, polyimide, and polyethylene terephthalate.

18. The display device of claim 15, further comprising:
a dam disposed on a surface of the display stack structure,
wherein the dam overlaps with the corner of the cover window in the plan view.

19. The display device of claim 18, wherein the protective member is in contact with a side surface of the dam but does not overlap with an upper surface of the dam.

20. The display device of claim 15, wherein the display stack structure further comprises:
a cover panel disposed on a first surface of the display panel; and
a polarizing member disposed on a second surface of the display panel opposed to the first surface,
wherein a side surface of the optical adhesive member protrudes outward from a side surface of the polarizing member and the display panel, and the side surface of the polarizing member and the display panel protrudes outward from a side surface of the cover panel in the plan view.
